(19) United States
(12) Patent Application Publication
(10) Pub. No.: US 2024/0054922 A1
(43) Pub. Date: Feb. 15, 2024

(54) ASSEMBLY FOR SENSORY REPRESENTATION OF RIGID COATINGS

(71) Applicant: SILICALIA, S.L., Real de Gandia (ES)

(72) Inventor: Alberto Martinez Carregui, Real de Gandia (ES)

(73) Assignee: SILICALIA, S.L., Real de Gandia (ES)

(21) Appl. No.: 18/257,956

(22) PCT Filed: Nov. 25, 2021
(86) PCT No.: PCT/ES2021/070851

§ 371 Date: Jun. 16, 2023

(30) Foreign Application Priority Data
Dec. 16, 2020 (ES) U202032700

(51) Int. Cl. G09F 5/00

(52) U.S. Cl. CPC G09F 5/00

(57) ABSTRACT

An assembly for the sensorial display of a rigid cladding with a particular surface finish, the sensorial display assembly comprising a tile (1), corresponding to a sample of a minor portion of the cladding to be displayed, of the same material and with the same surface finish as the cited cladding to be displayed; and wherein the sensorial display assembly further comprises, associated with said tile (1), for its joint storage and/or display, a flexible sheet (2) printed with a graphic pattern that visually reproduces, at full scale, the color and surface appearance of the cladding to be displayed, the surface of the flexible sheet (2) being several times larger than the surface of the tile (1).

### FIELD OF THE ART

The present invention relates to an assembly for the sensorial display of claddings, i.e. to a set of elements that allow the sensory properties of a rigid cladding to be realistically displayed and presented without the need to use large slabs of said cladding, which are extremely heavy and costly and are difficult to handle and transport.

This assembly would thus make it possible, in an easy, comfortable and economical way, to display cladding, for instance a slab of natural stone, artificial stone or ceramic, that typically has a surface area larger than one square meter and is heavy, for example more than ten kilos, in a realistic manner and without the need to handle said slabs, so as to allow a consumer to see a correct visualization of the ultimate appearance of the cladding once it has been installed, allowing them to pick the preferred cladding.

### STATE OF THE ART

The display of claddings, such as, for instance, slabs of natural stone, artificial stone, or ceramic, or flooring made of adjacent or assembled pieces of natural stone, artificial stone, natural wood, artificial wood, or ceramic, by means of a reproduction of at least one square meter of said cladding has been known for a long time. This makes it possible to display their sensory properties, such as color, texture, gloss, feel, etc. However, this solution requires a lot of space for its display, does not allow for the relocation of the cladding due to its large size and weight, and it consumes a lot of resources.

The use of smaller-sized tiles of said cladding, for instance using tiles of such a size and weight that will allow their handling by one single person—for example, the size of a sheet of paper or even smaller—to make it possible to appreciate the appearance of different types of cladding, thus allowing for one of them to be selected for one particular application, has also been known for a long time. This solution allows for a large number of samples to be stored in a small space, and also allows for their easy relocation, being also an economical solution. However, this solution does not allow to correctly visualize the appearance of a large surface covered with said cladding due to the small size of the sample, so the user can get the wrong idea of the ultimate appearance of the cladding.

Typically, tiles are used having a small surface and being easy to handle, but these small-sized pieces hinder the visualization of the actual appearance that a large surface clad with the same stone as the tile would have, for instance a floor, a wall or a kitchen countertop.

Typically, attempts to solve this problem entail the association of images that show a space where said cladding has been applied; for instance, photographs of a kitchen or a bathroom where said rigid cladding has been installed. However, the spatial and lighting conditions of the photographed spaces will never be identical to the conditions of the space where the rigid cladding is to be installed. In addition, a photograph where the cladding is not displayed at full scale does not allow the consumer to correctly perceive the visual properties of the cladding.

The present invention proposes a solution to this and other problems.

### BRIEF DESCRIPTION OF THE INVENTION

The present invention relates to an assembly for the sensorial display of a rigid cladding with a particular surface finish, i.e. to a set of elements intended to facilitate the appreciation of the appearance and other sensory qualities, such as the gloss, the texture, the feel, or the thermal feeling of a rigid cladding of large surface area, but without the disadvantages related to the storage, handling and transport of large-sized samples of said rigid cladding.

The surface finish of the cladding will be understood as the pattern, whether natural, artificial, regular, or irregular, visible on its surface—for instance, irregular veins in the case of cladding—made of, or simulating to be, natural stone or wood, a geometric pattern drawn on ceramic cladding.

Despite the foregoing, the preferred use of the invention will be to display the cladding of a kitchen countertop. Therefore, the proposed assembly comprises a flat tile that contains a portion of the rigid cladding, displaying the same surface finish as the cladding, so as to allow the user to perceive not only the visual qualities of the cladding, such as its appearance and gloss, but also its tactile qualities, such as its texture.

The tile is associated, for its joint storage and/or display, with a flexible sheet printed with a graphic pattern that visually reproduces, approximately at full scale, the color and surface appearance of the cladding to be displayed, the surface of the flexible sheet being several times larger than the surface area of the tile; for instance, at least ten times or preferably at least twenty times the surface area of the tile. It will be understood that the surface of an element is the surface of its front face.

It will be understood that “approximately at full scale” means that the printed image reproduces the appearance of the cladding, with a size close or identical to the actual size of the cladding. It will be understood that deviations in size of up to 10% larger or smaller than the actual size can also be considered as approximately full-scale reproductions.

Therefore, it is proposed that the assembly include a tile, by way of a small-sized physical sample—for instance of natural or artificial stone, ceramic, or wood—, that will allow to appreciate its visual and tactile qualities of finish, gloss, etc., and a flexible sheet larger than the tile printed with a graphic pattern, typically a life-size photograph of the same cladding making up the tile, and will allow to appreciate the appearance of a large surface covered with said cladding without the need to handle or transport large cladding slabs.

It will be understood that a tile is a rigid flat element with a weight and size adapted to its handling with one hand, typically with a weight less than 1000 g, preferably equal to or less than 500 g, usually rectangular in format.

In the case of artificial stone, since the vein pattern is repeatable, the flexible sheet can exactly reproduce the vein pattern that is actually to be installed, and not merely a vein pattern representative of a particular type of stone, as is the case with natural stone.

It will be understood that the association between the tile and the flexible sheet is effected by way of elements temporarily or permanently linking the constituting elements of the assembly that allow for their joint storage or display or which link them together by means of shared identification elements.

According to an embodiment of the invention, the flexible sheet can be a sheet of fabric, or of plastic, rayon or silk material, which provides a silky feel and stretches with ease without creases on a flat surface, in addition to allowing a compact storage in a small space without creasing.

The fabric making up the flexible sheet will preferably be a fabric with a loose drape, selected such that, by its own weight, will be perfectly adapted to any edge of the surface on which it stretches out.

It is proposed, for instance, that the tile and the flexible sheet be associated through their integration in one single holder, for example, stored in housings provided in the holder and/or permanently or removably attached to the holder.

Preferably, the flexible sheet is associated, stored and/or attached to the holder in a folded, pleated or rolled up position.

The holder can be, for instance, an envelope, box, case, fold-out catalog—such as, for example, a two or three-page leaflet—, a book-like catalog or roll-up stand, such as an oblong core around which the flexible sheet can be rolled up, or a holder integrating an oblong core, with or without a manual or automatic turning mechanism to roll up the flexible sheet around the oblong core.

The flexible sheet will be stored in the holder, preferably folded or rolled up, when it is not being displayed.

The tile will also be associated with said holder and, therefore, to the flexible sheet storable therein. For instance, the tile can also be storable inside a holder, together with the flexible sheet, or the tile can be attached to an external or internal face of the holder; for example, to its lid, or the tile can even make up at least one of the sides of the holder.

It is also proposed that the flexible sheet may have a panel attached having printed identification information related to said cladding.

According to a further optional embodiment, the tile and the flexible sheet are removably associated with one another by means of a coupling device, thus allowing for their temporary attachment and release. Said coupling device can include Velcro, magnets, clips, elastic bands, or can also include complementary fastening elements.

According to the latter embodiment, the tiles can be anchored to a vertical holder and include a fastening element that is complementary to another fastening element provided on the flexible sheet itself; for instance, the tile can include a hook and the tile a connection element to said hook.

According to a further embodiment, the tile and the flexible sheet are adhesively associated.

Preferably, the tile will have a surface area equal to or smaller than 500 cm² and/or a weight equal to or less than 500 g, or equal to or less than 250 g.

It is also proposed that multiple assemblies like the one described heretofore be grouped together to form a display set, each assembly showing a different cladding, with various visual qualities.

The tile will preferably have a thickness smaller than the cladding to be displayed.

The cladding may be a single large format slab of natural stone, artificial stone, or ceramic; for instance, one having a surface area equal to or larger than two square meters.

In such a case, the flexible sheet will reproduce the entire, or at least a major portion of, the cladding slab surface.

Alternatively, the cladding may be a group of adjacent flat pieces that jointly make up a cladding flat surface; for instance, pieces of natural stone, artificial stone, ceramic, natural wood, or artificial wood, grouped together to form flooring or a wall cladding.

It is also contemplated to use a plurality of flexible sheets, each one printed with an approximately true-to-scale display of a different cladding, for their joint display, typically by stretching them on a surface, allowing the user to compare between displays of different claddings and pick the one they like the most for its installation in a certain space. This would make it possible, for instance, to stretch the flexible sheets on a kitchen countertop so as to appreciate the appearance a particular cladding, visually displayed by the flexible sheet, would have, if said cladding were to be placed in that kitchen or an equivalent or similar one.

For certain applications, it is also contemplated that the flexible sheet may be used without being associated with a tile.

It is also contemplated that the flexible sheet, or the display assembly, may be mailed directly to the address where a cladding is to be installed so that the user can see, on site, the appearance of the installed cladding before its installation.

Preferably, the flexible sheet will measure at least 60 cm by 60 cm, preferably at least 60 cm by 100 cm, and more preferably at least 80 cm by 150 cm.

Other characteristics of the invention will appear in the following detailed description of an exemplary embodiment.

### BRIEF DESCRIPTION OF THE FIGURES

The foregoing and other advantages and characteristics will be more fully understood from the following detailed description of an exemplary embodiment with reference to the attached drawings, which must be taken by way of illustration and not limitation, wherein:

FIG. 1 shows a tile of natural or artificial stone with a vein pattern attached to the lid of a holder, which in this case is a box, and a stretched out flexible sheet that includes a full-scale display of a natural or artificial stone like that on the tile, including its vein pattern, the box being intended for storing the folded flexible sheet, allowing their association;

FIG. 2 shows a tile of natural or artificial stone with a vein pattern provided with a hook-shaped coupling device from which the flexible sheet hangs when stored, allowing their association;

FIG. 3 shows a tile of natural or artificial stone attached to a panel with information related to said stone, and a flexible sheet also attached to a panel with information related to said stone, allowing the association of the tile and the flexible sheet through the information contained in said information panels;

FIG. 4 shows the same assembly as FIG. 1, but according to an alternative embodiment wherein the storage and/or display assembly is a case with a hinged lid containing inner compartments, one of them intended for storing the tile and the other intended for storing the folded flexible sheet;

FIG. 5 shows an alternative embodiment, not comprised within the scope of the present invention, of the assembly shown in FIG. 4, wherein the cladding is formed by a set of ceramic paving tiles arranged in a particular pattern—a spike pattern in this example—and wherein the tile is one of said individual paving tiles.

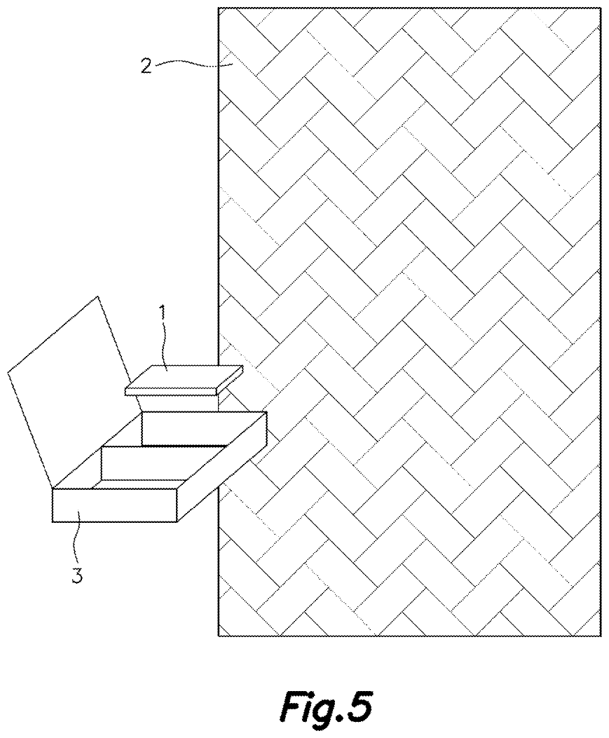

### DETAILED DESCRIPTION OF AN EXEMPLARY EMBODIMENT

The enclosed Figures show exemplary embodiments of the present invention by way of illustration and not limitation.

The present invention relates to an assembly that allows the visualization of natural or artificial stone surfaces in order to facilitate the selection of one particular type and/or color of stone with some particular vein pattern, for an application.

The assembly consists of a tile 1, made of some particular natural or artificial stone that includes a part of a vein pattern representative of said natural or artificial stone, and of a flexible sheet 2 larger than the tile 1 and which reproduces, at full scale, the same natural or artificial stone that constitutes the tile 1 and which, therefore, also includes parts of the vein pattern representative of said natural or artificial stone. Typically, the flexible sheet 2 will be printed with a photograph or a realistic image of said natural or artificial stone with as much chromatic fidelity as possible.

The tile 1 and the flexible sheet 2 are associated for their joint storage and/or display, allowing the flexible sheet 2 to be stretched out covering a large surface, facilitating the visualization of the effect produced by certain natural or artificial stone when covering large surfaces, while facilitating their storage and transport. The tile 1 allows to appreciate other qualities typical of the material, such as gloss or feel, that do not require large surfaces for their correct assessment.

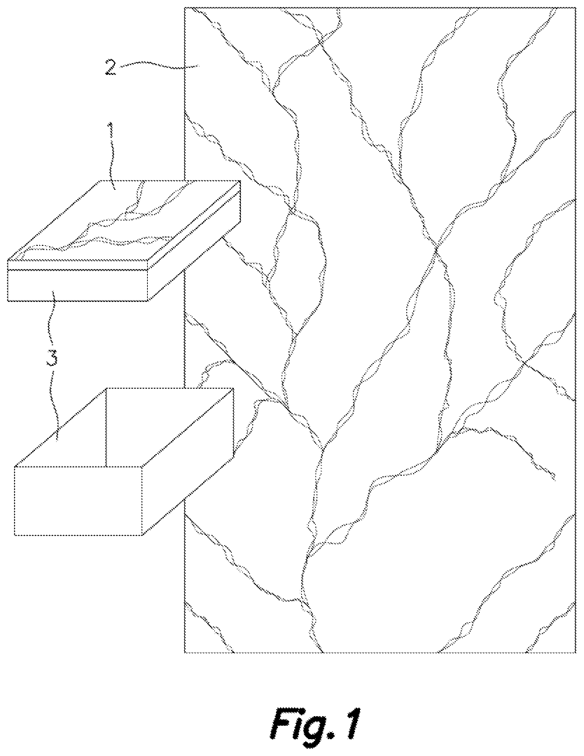

According to a first embodiment of the invention, shown in FIG. 1, the tile 1 of natural or artificial stone is adhered to the lid of a holder 3, which in this case is a box, sized to store and transport the folded or rolled up flexible sheet 2 when not on display, said tile 1 and flexible sheet 2 being thus associated with one another through said holder 3 constituted by the box.

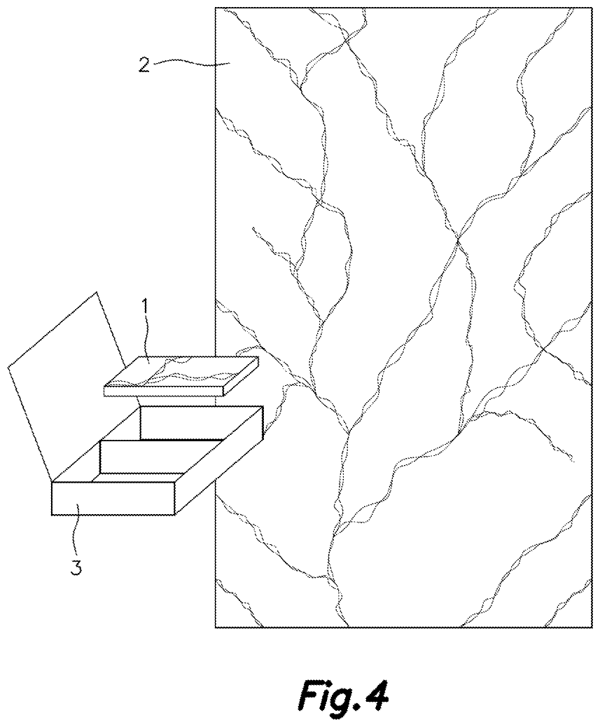

Obviously, other variations of this assembly are contemplated, such as, for instance, that the tile 1 be the lid of the holder 3, that the tile 1 be adhered to the interior of the lid, that the tile 1 be adhered to other outer surfaces of the holder 3, that it constitute some of the sides of the holder 3, or that the tile 1 not be adhered to the holder 3, but that it should be stored therein when not on display, as shown in FIG. 4. In this case, the holder 3 may include specific compartments for the tile 1 and for the folded flexible sheet 2.

The holder 3 may be provided with a removable lid, a hinged lid, or it may have a drawer-like opening. Alternatively, the holder 3 may be an envelope, allowing for the easy and economical postal delivery directly to the users' premises so requesting, or a two or three-page leaflet-type fold-out catalog or the like, or a book-like catalog on which the different tiles 1 and/or flexible sheets 2 are adhered.

The inclusion of an elastic band or a magnet for closing the lid of the holder 3 is also proposed, by way of example, thus keeping the tile 1 in its position.

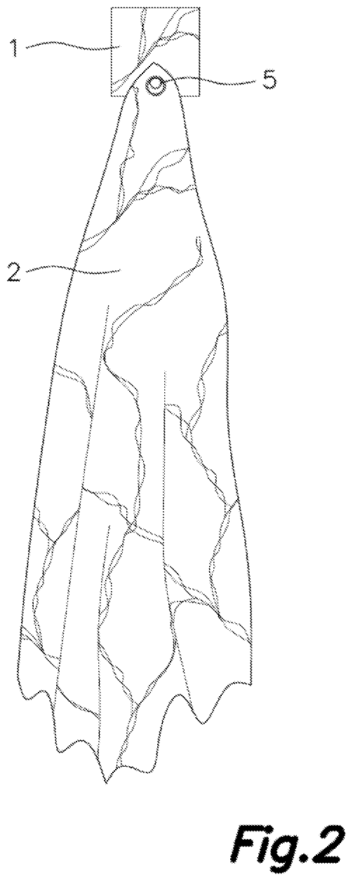

According to an alternative embodiment shown in FIG. 2, the tile 1 is removably associated with the flexible sheet by means of a holder 3 in the form of a coupling device 5.

In this embodiment the tile 1 is fixed to a vertical holder, such as a wall, and the coupling device 5 is a complementary hook with an eyelet provided on the flexible sheet 2, which allows the flexible sheet 2 of the tile 1 to be hung for its storage when not on display.

Other embodiments of the coupling device 5 are also contemplated, such as, for instance, the use magnets, Velcro, clips, or clamps, or other releasable fastening means.

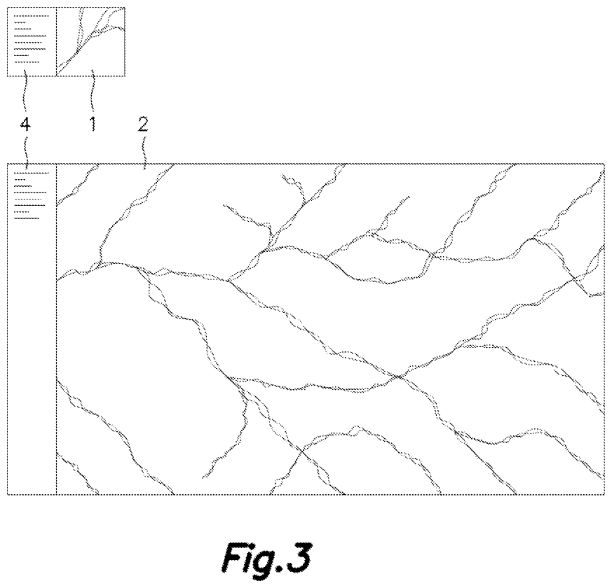

According to a further embodiment, shown in FIG. 3, the tile 1 includes a panel 4 with identification information related to the stone the tile 1 is composed of, and the flexible sheet 2 also includes a panel 4 with identification information related to the stone displayed on the flexible sheet 2, which is the same one constituting the tile 1. Said identification information allows the association of the tile 1 and the flexible sheet 2.

Panel 4 can also serve as a holder or guide for folding or rolling up the flexible sheet for its storage. For instance, the panel can encompass the entire side of the flexible sheet, which is preferably rectangular, allowing said flexible sheet to be rolled around the panel 4. The panel may protrude from one or both ends of the flexible sheet 2, rolled around it, including identifying information, such as, for instance, a name.

It is also contemplated that the tile 1 be adhered to the flexible sheet 2, thus effecting their association.

1. An assembly for the sensorial display of a rigid cladding with a particular surface finish, the sensorial display assembly comprising a tile, corresponding to a sample of a minor portion of the rigid cladding to be displayed and comprising of the same material and the same surface finish as the rigid cladding to be displayed;
the sensorial display assembly further comprises a flexible sheet associated with the tile for its joint storage and/or joint display and comprising a printed graphic pattern that visually reproduces, approximately at full scale, the color and surface appearance of the rigid cladding to be displayed, the surface of the flexible sheet being several times larger than the surface of the tile, and
the cladding comprising one single slab of natural stone, artificial stone, or ceramic, and the flexible sheet comprising a sheet of fabric, rayon or silk material.

2. (canceled)

3. The sensorial display assembly according to claim 1 wherein the tile and the flexible sheet are associated:
through their integration in one single holder; or
through their integration in one single holder in the shape of an envelope, box, case, fold-out catalog, book-like catalog, or roll-up stand; or
with one another in a removable way by a coupling device; or
with one another in a removable way by a coupling device in the shape of complementary fastening elements, Velcro, clips, clamps or magnets; or
through the inclusion, both on the tile and on the flexible sheet, of the same written information identifying the rigid cladding being displayed.

4. The sensorial display assembly according to claim 3 wherein the tile and the flexible sheet are integrated in the one single holder through their storage in housings provided in the holder and/or through their permanent or removable attachment to the one single holder.

5. The sensorial display assembly according to claim 3 wherein the flexible sheet is integrated into the one single holder in a folded, pleated or rolled up position during its storage.

6. The sensorial display assembly according to claim 1 wherein the tile has a surface area equal to or smaller than 500 cm² and/or a weight equal to or less than 500 g, or equal to or less than 250 g.

7. The sensorial display assembly according to claim 1 wherein the flexible sheet has a surface area at least ten times, or preferably at least twenty times, larger than the surface area of the tile.

8. The sensorial display assembly according to claim 1 wherein the tile has a thickness smaller than the rigid cladding to be displayed.

9. (canceled)

10. The sensorial display assembly according to claim 1 wherein the flexible sheet reproduces the entire, or at least a major portion of, the slab surface.

11. (canceled)

12. (canceled)

13. The sensorial display assembly according to claim 4 wherein the flexible sheet is integrated into the one single holder in a folded, pleated or rolled up position during its storage.
